(19) United States
(12) Patent Application Publication
(10) Pub. No.: US 2026/0271703 A1
(43) Pub. Date: Sep. 10, 2026

(54) SEMICONDUCTOR DEVICE AND LAMINATED STRUCTURE

(71) Applicant: SONY SEMICONDUCTOR SOLUTIONS CORPORATION, Kanagawa (JP)

(72) Inventor: Junichiro FUJIMAGARI, Kanagawa (JP)

(73) Assignee: SONY SEMICONDUCTOR SOLUTIONS CORPORATION, Kanagawa (JP)

(21) Appl. No.: 18/876,755

(22) PCT Filed: Jun. 23, 2023
(86) PCT No.: PCT/JP2023/023391

§ 371 Date: Dec. 19, 2024

(30) Foreign Application Priority Data
Jun. 30, 2022 (JP) 2022-106529

(51) Int. Cl. H10W 20/47; H10F 39/95; H10W 20/00; H10W 20/41; H10W 20/42; H10W 90/26

(52) U.S. Cl. CPC H10W 20/47; H10F 39/95; H10W 20/075; H10W 20/42; H10W 20/435; H10W 90/26

(57) ABSTRACT

A semiconductor device according to an embodiment of the present disclosure includes: a semiconductor chip including a first pad, a first wiring, and a first insulating film; a second insulating film provided on the semiconductor chip and having a flat surface; and a second pad provided on the second insulating film and including a metal material. The second pad is electrically coupled to the first pad or the first wiring, and is provided up to the surface of the second insulating film.

### DESCRIPTION

### Technical Field

The present disclosure relates to a semiconductor device and a laminated structure.

### Background Art

A unit having a semiconductor substrate and a memory chip coupled by a first rewiring section, a first connection pad, a bump, a second connection pad, and a second rewiring section has been proposed.

### CITATION LIST

### Patent Literature

Patent Literature 1: Japanese Unexamined Patent Application Publication No. 2019-68049

### SUMMARY OF THE INVENTION

What is desired in a semiconductor device is to allow for bonding between metal electrodes.

It is desirable to provide a semiconductor device suitable for bonding between metal electrodes.

A semiconductor device according to one embodiment of the present disclosure includes: a semiconductor chip including a first pad, a first wiring, and a first insulating film; a second insulating film provided on the semiconductor chip and having a flat surface; and a second pad provided on the second insulating film and including a metal material. The second pad is electrically coupled to the first pad or the first wiring, and is provided up to the surface of the second insulating film.

A laminated structure according to one embodiment of the present disclosure includes: a semiconductor substrate; a wiring layer stacked on the semiconductor substrate; and a semiconductor device stacked on the wiring layer. The semiconductor device includes: a semiconductor chip including a first pad, a first wiring, and a first insulating film; a second insulating film provided on the semiconductor chip and having a flat surface; and a second pad provided on the second insulating film and including a metal material. The second pad is electrically coupled to the first pad or the first wiring, and is provided up to the surface of the second insulating film. The wiring layer has a third pad bonded to the second pad.

### BRIEF DESCRIPTION OF THE DRAWINGS

FIG. 1 is a diagram illustrating a schematic configuration example of a semiconductor device according to an embodiment of the present disclosure.

FIG. 2 is a diagram for explaining a configuration example of the semiconductor device according to an embodiment of the present disclosure.

FIG. 3 is a diagram for explaining a configuration example of the semiconductor device according to an embodiment of the present disclosure.

FIG. 4A is a diagram illustrating a method of manufacturing the semiconductor device according to an embodiment of the present disclosure.

FIG. 4B is a diagram illustrating the method of manufacturing the semiconductor device according to an embodiment of the present disclosure.

FIG. 4C is a diagram illustrating the method of manufacturing the semiconductor device according to an embodiment of the present disclosure.

FIG. 4D is a diagram illustrating the method of manufacturing the semiconductor device according to an embodiment of the present disclosure.

FIG. 4E is a diagram illustrating the method of manufacturing the semiconductor device according to an embodiment of the present disclosure.

FIG. 5A is a diagram illustrating a configuration example of a semiconductor device according to a first modification example of the present disclosure.

FIG. 5B is a diagram illustrating another configuration example of the semiconductor device according to the first modification example of the present disclosure.

FIG. 5C is a diagram illustrating another configuration example of the semiconductor device according to the first modification example of the present disclosure.

FIG. 6A is a diagram illustrating a configuration example of a semiconductor device according to a second modification example of the present disclosure.

FIG. 6B is a diagram illustrating another configuration example of the semiconductor device according to the second modification example of the present disclosure.

FIG. 6C is a diagram illustrating another configuration example of the semiconductor device according to the second modification example of the present disclosure.

FIG. 6D is a diagram illustrating another configuration example of the semiconductor device according to the second modification example of the present disclosure.

FIG. 7A is a diagram illustrating a configuration example of a semiconductor device according to a third modification example of the present disclosure.

FIG. 7B is a diagram illustrating another configuration example of the semiconductor device according to the third modification example of the present disclosure.

FIG. 8A is a diagram illustrating a configuration example of a semiconductor device according to a fourth modification example of the present disclosure.

FIG. 8B is a diagram illustrating another configuration example of the semiconductor device according to the fourth modification example of the present disclosure.

FIG. 9 is a diagram illustrating a configuration example of a semiconductor device according to a fifth modification example of the present disclosure.

FIG. 10 is a diagram illustrating another configuration example of the semiconductor device according to the fifth modification example of the present disclosure.

FIG. 11A is a diagram for explaining a layout example of rewiring of the semiconductor device according to the fifth modification example of the present disclosure.

FIG. 11B is a diagram for explaining a layout example of the rewiring of the semiconductor device according to the fifth modification example of the present disclosure.

FIG. 11C is a diagram for explaining a layout example of the rewiring of the semiconductor device according to the fifth modification example of the present disclosure.

### MODES FOR CARRYING OUT THE INVENTION

Hereinafter, embodiments of the present disclosure will be described in detail with reference to the drawings. The description will be made in the following order.
1. Embodiment
2. Modification Examples
2-1. First Modification Example
2-2. Second Modification Example
2-3. Third Modification Example
2-4. Fourth Modification Example
2-5. Fifth Modification Example

### 1. Embodiment

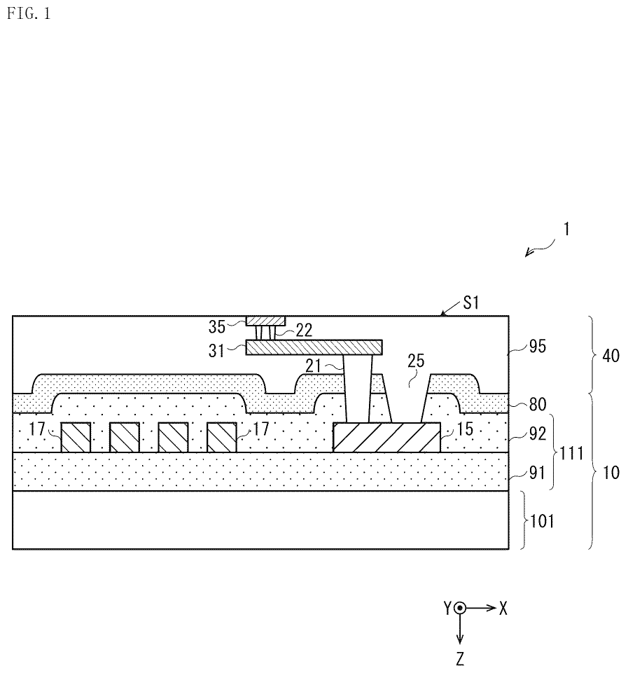

FIG. 1 is a diagram illustrating a schematic configuration example of a semiconductor device according to an embodiment of the present disclosure. FIG. 1 illustrates an example of a cross-sectional configuration of a semiconductor device 1. As illustrated in FIG. 1, the semiconductor device 1 includes a semiconductor chip 10 and a rewiring layer 40. Examples of the semiconductor chip 10 include a processor, a memory, a sensor, and other integrated circuits. As an example, the semiconductor chip 10 may be a general-purpose memory, a general-purpose logic, or a custom design chip.

The semiconductor chip 10 may be, for example, a general-purpose memory such as a DRAM (Dynamic Random Access Memory), a SRAM (Static Random Access Memory), or a MRAM (Magnetic Random Access Memory). Further, the semiconductor chip 10 may be a general-purpose logic such as a DSP (Digital Signal Processor) or an FPGA (Field Programmable Gate Array).

As an example, it is possible to obtain the semiconductor device 1 illustrated in FIG. 1 by forming the rewiring layer 40 on the semiconductor chip 10 of a finished product such as a general-purpose memory or a general-purpose logic. A pad of the semiconductor chip 10 and a pad of the rewiring layer 40 are electrically coupled to each other.

The semiconductor device 1 has a configuration in which the semiconductor chip 10 and the rewiring layer 40 are stacked in a Z-axis direction. It should be noted that, as illustrated in FIG. 1, a left-right direction of a paper surface orthogonal to the Z-axis direction is defined as an X-axis direction, and directions orthogonal to a Z-axis and an X-axis are defined as a Y-axis direction. In the following drawings, a direction may sometimes be expressed with reference to a direction of an arrow in FIG. 1.

The semiconductor chip 10 includes a first substrate 101, a wiring layer 111, and a protective film 80. The first substrate 101 is configured by a semiconductor substrate (for example, a silicon substrate). Various circuit elements configuring the semiconductor chip 10, such as a transistor, a diode, a resistor, and a capacitor, may be formed on the first substrate 101. The first substrate 101 may include a compound semiconductor material.

A wiring layer 111 is provided on an upper surface of the first substrate 101. The wiring layer 111 includes, for example, a conductive film and an insulating film, and includes a plurality of wirings, a via (VIA), and the like. The wiring layer 111 includes, for example, two or more layers of wiring. The wiring layer 111 has, for example, a configuration in which a plurality of wirings is stacked with an insulating film therebetween.

The wiring layer 111 includes aluminum (Al), copper (Cu), tungsten (W), polysilicon (Poly-Si), or the like. The insulating film includes, for example, silicon oxide (SiO), silicon nitride (SiN), silicon oxynitride (SiON), or the like. The insulating film may also be referred to as an interlayer insulating film (an interlayer insulating layer). The first substrate 101 and the wiring layer 111 may be collectively referred to as the first substrate 101 (or a first circuit layer).

As illustrated in FIG. 1, a protective film 80 is provided on the wiring layer 111. The protective film 80 is a passivation film (a protective layer) and is so formed as to cover an entire surface of the wiring layer 111. It should be noted that the semiconductor chip 10 may not have the protective film 80.

In an example illustrated in FIG. 1, the semiconductor chip 10 includes an insulating film 91 and an insulating film 92. The insulating film 91 and the insulating film 92 are each configured by, for example, a single-layer film including one of an oxide film (for example, a silicon oxide film), a nitride film (for example, a silicon nitride film), and an oxynitride film, or a stacked film configured by two or more of these films. The insulating film 92 is stacked on the insulating film 91. The protective film 80 is formed on the insulating film 92.

The wiring 17 illustrated in FIG. 1 is, for example, a wiring that includes aluminum (Al). It should be noted that the wiring 17 may include another metal material. The plurality of wirings 17 is formed inside the insulating film 92 and is positioned on the insulating film 91. The respective wirings 17 are spaced apart from each other in the X-axis direction. In an example illustrated in FIG. 1, the plurality of wirings 17 is configured by uppermost wirings in the wiring layer 111.

The wiring 17 is a power supply wiring, a GND (ground) wiring, a signal-transmission wiring, or the like. It should be noted that the plurality of wirings 17 may be arranged side by side with an air gap interposed therebetween. Providing the air gap between the adjacent wirings 17 makes it possible to reduce a parasitic capacitance added to the wiring 17.

In the semiconductor chip 10, a pad 15 (PAD) is provided. The pad 15 is, for example, an electrode that includes aluminum. It should be noted that the pad 15 may include another metal material. In the semiconductor chip 10, the plurality of pads 15 electrically coupled to a circuit element inside the semiconductor chip 10 is disposed. The pad 15 illustrated in FIG. 1 is positioned on the insulating film 91 and is formed inside the insulating film 92.

In the semiconductor chip 10, an opening 25 on the pad 15 is formed, and the pad 15 is partially exposed by the opening 25. The opening 25 is defined by an end face of each of the protective film 80 and the insulating film 92. The opening 25 is a hole (a penetrating hole) that penetrates the protective film 80 and the insulating film 92. It should be noted that the pad 15 can be referred to as a pad electrode, and the opening 25 is also a pad opening. The pad 15 can also be referred to as a terminal (a connection terminal) of the semiconductor chip 10.

The plurality of pads 15 may be disposed on the semiconductor chip 10. For example, the plurality of pads 15 may include a power supply pad and a GND pad, and may supply a power supply voltage and a GND voltage (a ground voltage) to each circuit of the semiconductor chip 10.

Further, for example, the plurality of pads 15 of the semiconductor chip 10 may include a pad used for transmission of a signal to the outside. For example, the plurality of pads 15 includes an input/output pad for inputting and outputting a signal, an input pad for inputting a signal from the outside of the semiconductor chip 10, an output pad for outputting a signal to the outside of the semiconductor chip 10, and the like.

The rewiring layer 40 includes, for example, a conductor film and an insulating film, and includes a plurality of rewirings, vias, and the like. The rewiring layer 40 includes one layer or two or more layers of rewiring. The rewiring layer 40 may have a configuration in which wirings are stacked with an insulating film therebetween. The rewiring, which is a wiring of the rewiring layer 40, includes aluminum, copper, or the like. The rewiring is, for example, a wiring used for an electrical connection between a circuit of the semiconductor chip 10 and an external circuit.

In an example illustrated in FIG. 1, the rewiring layer 40 includes a via 21, a via 22, a rewiring 31, a pad (referred to as a connection pad 35), and an insulating film 95. It should be noted that the number and arrangement of the pad 15, the connection pad 35, the via 21, the via 22, the rewiring 31, and the like are not limited to the illustrated example. For example, although only one pad 15 and one connection pad 35 are illustrated in FIG. 1, the plurality of pads 15 and the plurality of connection pads 35 are disposed in the semiconductor device 1.

The via 21 electrically couples the pad 15 and the rewiring 31. The via 21 includes, for example, tungsten (W), aluminum (Al), cobalt (Co), or the like. The via 21 is formed between the pad 15 of the semiconductor chip 10 and the rewiring 31. In the present embodiment, the via 21 is provided around the opening 25 as illustrated in FIG. 1.

The via 21 extends in the Z-axis direction around the opening 25, and is so disposed as to penetrate a part of the protective film 80 and a part of the insulating film 92. The via 21 penetrates a part of the protective film 80 and a part of the insulating film 92, and couples the pad 15 and the rewiring 31. The via 21 is formed from the rewiring 31 to the pad 15, and a part of the via 21 is provided inside the wiring layer 111.

The via 22 electrically couples the connection pad 35 and the rewiring 31. The via 22 includes, for example, tungsten, aluminum, cobalt, or the like. The via 22 is formed between the connection pad 35 and the rewiring 31, and couples the connection pad 35 and the rewiring 31.

In the semiconductor device 1, as illustrated in FIG. 1, a size of the via 21 is larger than a size of the via 22. A width of the via 21 in the X-axis direction is larger than a width of the via 22 in the X-axis direction. A diameter of the via 21 is, for example, 1 um or more. By coupling the relatively large via 21 to the pad 15, it is possible to ensure a contact property with the pad 15.

The connection pad 35 is, for example, an electrode that includes copper (Cu). In the rewiring layer 40 of the semiconductor device 1, for example, the plurality of connection pads 35 is provided corresponding to the number of pads 15 of the semiconductor chip 10. The connection pad 35 may include a metal material other than copper, for example, nickel (Ni), cobalt (Co), tin (Sn), gold (Au), or the like.

The connection pad 35 is electrically coupled to the pad 15 of the semiconductor chip 10, and is provided up to a surface S1 (an end face) of the insulating film 95 as illustrated in FIG. 1. The connection pad 35 is provided in the insulating film 95 and reaches the surface S1 of the insulating film 95. That is, the connection pad 35 is positioned up to the surface S1 of the insulating film 95. In an example illustrated in FIG. 1, the connection pad 35 is electrically coupled to the pad 15 via the rewiring 31. The connection pad 35 is an electrode used for bonding between metal electrodes, and serves as a bonding electrode.

The insulating film 95 is provided on the semiconductor chip 10, and has the flat surface S1 as illustrated in FIG. 1. The insulating film 95 is configured by, for example, a single-layer film including one of an oxide film, a nitride film, an oxynitride film, and the like, or a stacked film including two or more of these films. The via 22, the rewiring 31, and a part of the via 21 are provided inside the insulating film 95.

The connection pad 35 is so provided that a surface (an end face) of the connection pad 35 is exposed from the insulating film 95. The connection pad 35 is provided up to the surface S1 (the end face) of the insulating film 95, and serves as a pad exposed to the outside from the insulating film 95. As described above, the surface S1 of the insulating film 95 has a flat shape. Therefore, it is possible to perform the bonding between the metal electrodes by using the connection pad 35 which is a metal electrode.

For example, the semiconductor chip 10 and another semiconductor chip are bonded to each other by bonding between metal electrodes that include Cu, that is, by Cu—Cu bonding. The other semiconductor chip includes a processor, a memory, a sensor, any other integrated circuit, and the like. For example, the other semiconductor chip is a general-purpose memory, a general-purpose logic, or a custom design chip.

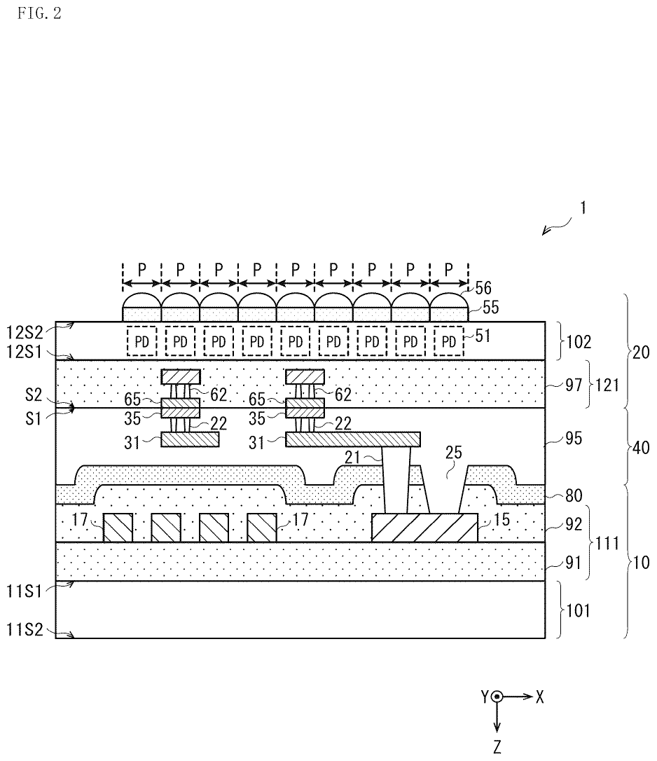

FIG. 2 is a diagram for describing a configuration example of the semiconductor device according to the embodiment. FIG. 2 schematically illustrates an example in which the above-described semiconductor chip 10 and a semiconductor chip 20 having a light receiving element 51 are bonded by the bonding between the metal electrodes. The semiconductor device 1 has a configuration in which the semiconductor chip 10 including the first substrate 101 and the semiconductor chip 20 including the second substrate 102 are stacked in the Z-axis direction. The first substrate 101 and the second substrate 102 are each configured by a semiconductor substrate (for example, a silicon substrate).

As illustrated in FIG. 2, the first substrate 101 and the second substrate 102 respectively have first surfaces 11S1 and 12S1 and second surfaces 11S2 and 12S2. For example, each of the first surfaces 11S1 and 12S1 is an element forming surface on which an element such as a transistor is formed. A gate electrode, a gate oxide film, and the like are provided on each of the first surfaces 11S1 and 12S1. As described above, the wiring layer 111 is provided on the first surface 11S1 of the first substrate 101.

The second substrate 102 is provided with a plurality of pixels P each having the light receiving element 51. The light receiving element 51 (a light receiving section) of each pixel P is, for example, a photodiode, and may receive light and generate electric charges by photoelectric conversion. The light receiving element 51 is a photoelectric converter, and is configured to allow for the photoelectric conversion of light.

On the second surface 11S2 side of the second substrate 102, for example, a lens 56 that condense light, a filter 55, and the like are provided for each pixel P. The filter 55 is configured to selectively transmit light in a specific wavelength range of the incident light. The filter 55 is, for example, a RGB color filter, a filter that transmits infrared light, or the like.

As illustrated in FIG. 2, the wiring layer 121 is provided on the first surface 12S1 of the second substrate 102. The wiring layer 121 includes, for example, a conductor film and an insulating film, and includes a plurality of wirings, vias, and the like. The wiring layer 121 includes, for example, two or more layers of wiring. The wiring layer 121 has, for example, a configuration in which a plurality of wirings is stacked with an insulating film therebetween.

The wiring layer 121 includes aluminum, copper, tungsten, polysilicon, or the like. The insulating film includes, for example, silicon oxide, silicon nitride, silicon oxynitride, or the like. It should be noted that the second substrate 102 and the wiring layer 121 may be collectively referred to as the second substrate 102 (or a second circuit layer).

In an example illustrated in FIG. 2, the wiring layer 121 includes a via 62, a pad (referred to as a connection pad 65), and an insulating film 97. It should be noted that the number and arrangement of the connection pad 65 and the via 62 are not limited to the illustrated example. The via 62 electrically couples the connection pad 65 and the wiring of the wiring layer 121. The via 62 is includes, for example, tungsten, aluminum, cobalt, or the like.

The connection pad 65 is an electrode that includes, for example, copper (Cu). The connection pad 65 may include a metal material other than copper, for example, nickel, cobalt, tin, gold, or the like. The connection pad 65 is electrically coupled to an inner circuit of the semiconductor chip 20, and is provided up to a surface S2 of the insulating film 97 as illustrated in FIG. 2.

In an example illustrated in FIG. 2, the connection pad 65 is electrically coupled to an internal circuit of the semiconductor chip 20 via the via 62. The connection pad 65 is an electrode used for the bonding between the metal electrodes, and serves as a bonding electrode.

The insulating film 97 has the flat surface S2 similar to the surface S1 of the insulating film 95 of the semiconductor chip 10 described above. The insulating film 97 is configured by, for example, a single-layer film including one of an oxide film, a nitride film, an oxynitride film, and the like, or a stacked film including two or more of these films.

The connection pad 65 is so provided that the surface (the end face) of the connection pad 65 is exposed from the insulating film 97. The connection pad 65 is provided up to the surface S2 (the end face) of the insulating film 97, and serves as a pad exposed to the outside from the insulating film 97. The connection pad 65 is provided in the insulating film 97 and reaches the surface S2 of the insulating film 97. That is, the connection pad 65 is positioned up to the surface S2 of the insulating film 97. As described above, the surface S2 of the insulating film 97 has a flat shape.

The semiconductor chip 10 and the semiconductor chip 20 are so stacked that the first surface 11S1 of the first substrate 101 and the first surface 12S1 of the second substrate 102 are opposed to each other by the bonding between the metal electrodes. Bonding the plurality of connection pads 35 in the insulating film 95 and the plurality of connection pads 65 in the insulating film 97 couples the first substrate 101 and the second substrate 102 to each other.

As described above, in the present embodiment, the semiconductor chip is provided with the insulating film having the flat surface and the connection pad. In this way, it is possible to stack the plurality of semiconductor chips by bonding between the metal electrodes, for example, Cu—Cu bonding. The semiconductor chips are stacked by the Cu—Cu bonding, making it possible to promote a miniaturization as compared with a case where the semiconductor chips are stacked using bumps.

Further, in the present embodiment, it is possible to bond various semiconductor chips including general-purpose products. In FIG. 2, for example, it is possible to stack the semiconductor chip 20 having the light receiving element and the semiconductor chip 10 such as a general-purpose memory or a general-purpose logic to achieve the high-performance semiconductor device 1.

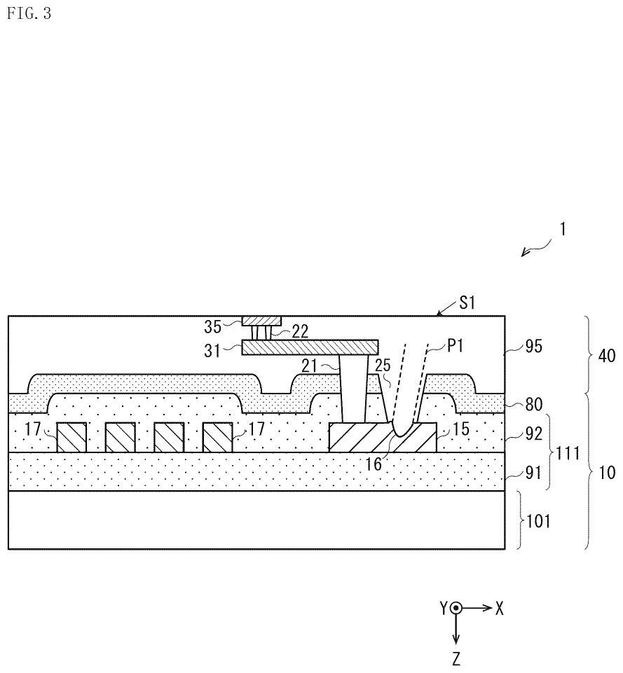

It should be noted that, as schematically illustrated in FIG. 3, there is a case where a needle mark 16 is generated in the pad 15 of the semiconductor chip 10. For example, in an inspection process of the semiconductor chip 10, a probe (a needle) P1 indicated by a broken line comes into contact with the pad 15 inside the opening 25, causing an undulation in the pad 15 and forming the needle mark 16. The needle mark 16 of the pad 15 has a shape including, for example, irregularities. Therefore, it is difficult to dispose the via 21 inside the opening 25.

Accordingly, in the present embodiment, as described above, the via 21 is formed in a region around the opening 25 and is coupled to the pad 15. Therefore, it is possible to form the via 21 with high accuracy, and to prevent an insufficient contact with the pad 15.

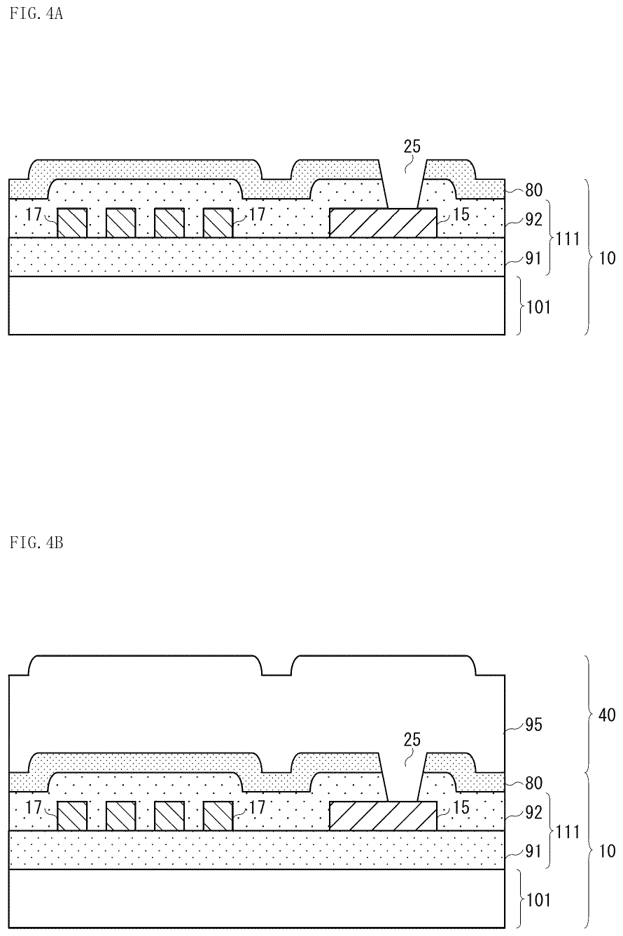

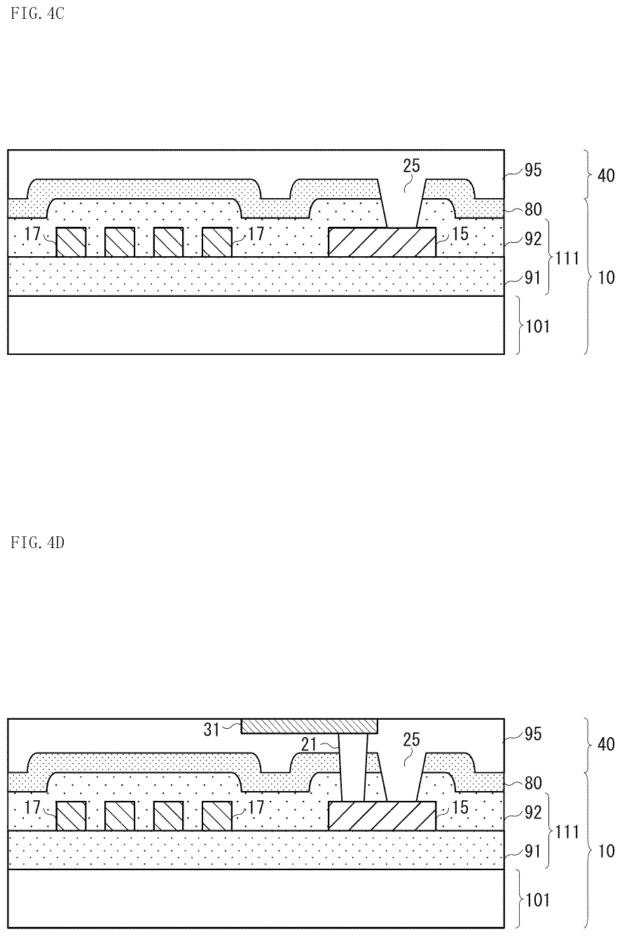

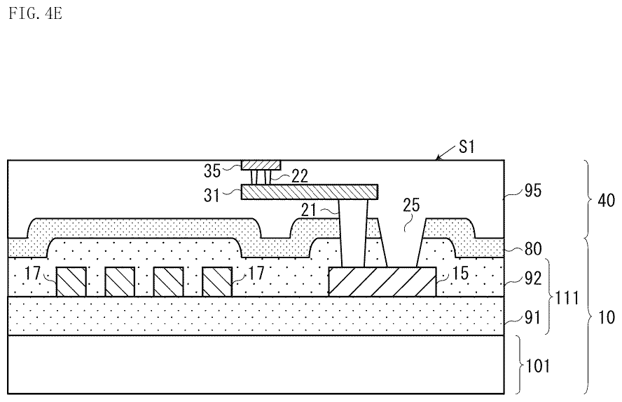

FIGS. 4A to 4E are diagrams illustrating an exemplary process of manufacturing the semiconductor device according to the embodiment. First, as illustrated in FIG. 4A, the semiconductor chip 10 such as a general-purpose memory is prepared. Next, as illustrated in FIG. 4B, an insulating film 95 is formed on the semiconductor chip 10. Thereafter, as illustrated in FIG. 4C, an unwanted part of the insulating film 95 is removed by a CMP (Chemical Mechanical Polishing).

Next, as illustrated in FIG. 4D, a trench (a hole) is formed by lithography and etching, and a metal plating is performed to form the via 21. In addition, as illustrated in FIG. 4D, the rewiring 31 is formed on the via 21. Thereafter, as illustrated in FIG. 4E, the insulating film 95 is formed, and the via 22 and the connection pads 35 are formed.

The connection pad 35 is exposed to the flat surface S1 of the insulating film 95.

It is possible to manufacture the semiconductor device 1 illustrated in FIG. 1 by the above-described manufacturing method. It should be noted that the above-described manufacturing method is merely an example, and any other manufacturing method may be employed.

### [Workings and Effects]

A semiconductor device (the semiconductor device 1) according to the present embodiment includes: a semiconductor chip (the semiconductor chip 10) including a first pad (the pad 15), a first wiring (the wiring 17), and a first insulating film (the insulating film 92 and the insulating film 91); a second insulating film (the insulating film 95) provided on the semiconductor chip and having a flat surface; and a second pad (the connection pad 35) provided on the second insulating film and including a metal material. The second pad is electrically coupled to the first pad or the first wiring, and is provided up to the surface of the second insulating film.

In the semiconductor device 1 according to the present embodiment, the insulating film 95 having the flat surface and the connection pad 35 are provided on the semiconductor chip 10. Thus, it is possible to perform the bonding between the metal electrodes, for example, the Cu—Cu bonding, using various semiconductor chips such as general-purpose memories. It is possible to provide a semiconductor device suitable for bonding between metal electrodes.

Next, modification examples of the present disclosure will be described. Hereinafter, the same components as those in the above-described embodiment are denoted by the same reference numerals, and description thereof will be omitted as appropriate.

### 2. Modification Examples

### (2-1. First Modification Example)

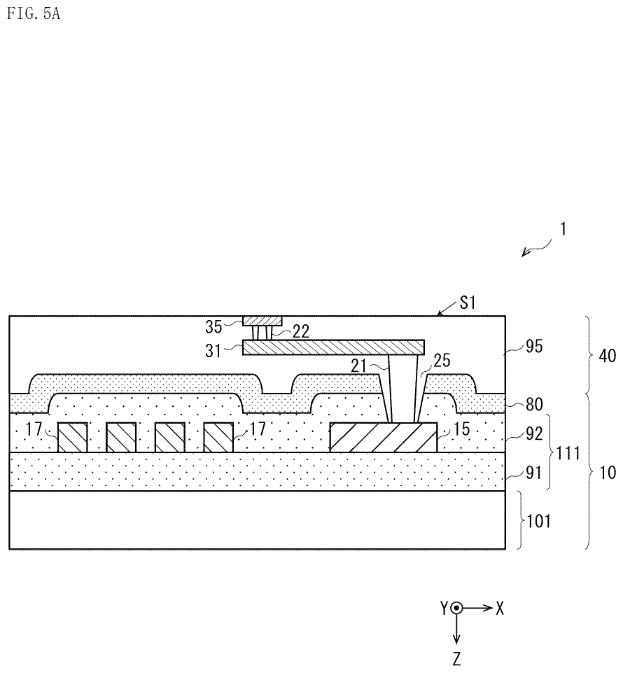

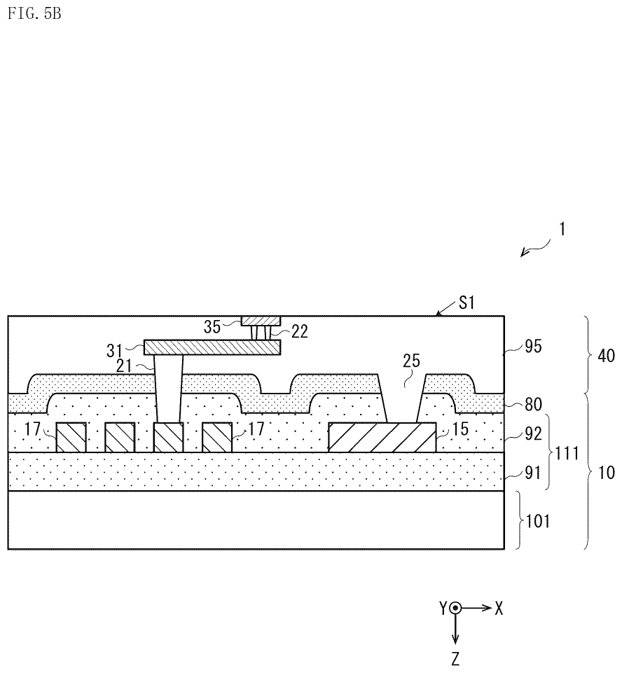

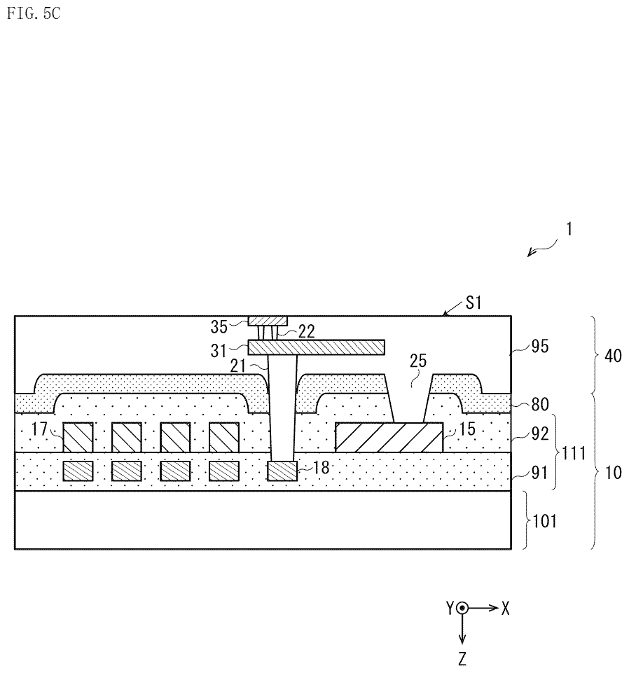

In the above-described embodiment, a configuration example of the semiconductor device has been described, but the configuration of the semiconductor device is not limited thereto. FIG. 5A is a diagram illustrating a configuration example of a semiconductor device according to a first modification example of the present disclosure. As illustrated in FIG. 5A, the via 21 may be provided inside the opening 25. The via 21 extends in the Z-axis direction inside the opening 25 and is coupled to the pad 15.

In the above-described embodiment, an example in which the connection pad 35 is electrically coupled to the pad 15 has been described, but the connection pad 35 may be electrically coupled to a wiring of the wiring layer 111. FIGS. 5B and 5C are diagrams illustrating other configuration examples of the semiconductor device according to the first modification example. For example, as illustrated in FIG. 5B, the connection pad 35 may be electrically coupled to the wiring 17 of the wiring layer 111. In an embodiment illustrated in FIG. 5B, the connection pad 35 is electrically coupled to the wiring 17 in the insulating film 92 through the via 22, the rewiring 31, and the via 21.

Further, as illustrated in FIG. 5C, the connection pad 35 may be electrically coupled to the wiring 18 of the wiring layer 111. The wiring 18 is positioned inside the insulating film 91, and is provided in a layer different from the pad 15 and the wiring 17. In an embodiment illustrated in FIG. 5C, the connection pad 35 is electrically coupled to the wiring 18 inside the insulating film 91 through the via 22, the rewiring 31, and the via 21. Also in a case of the present modification example, it is possible to obtain similar effects to those of the above-described embodiment.

### (2-2. Second Modification Example)

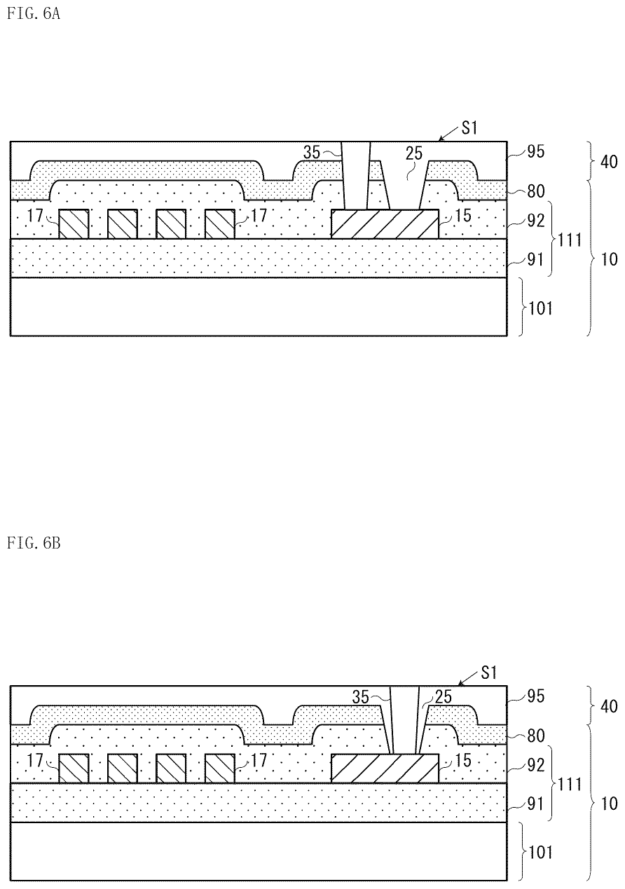

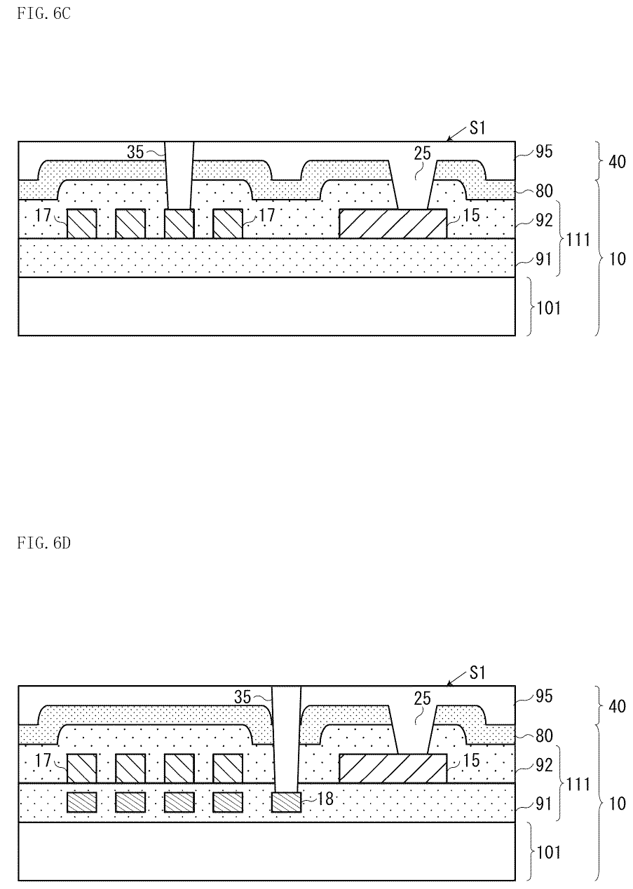

FIGS. 6A to 6D are diagrams illustrating configuration examples of a semiconductor device according to a second modification example. The connection pad 35 may be directly coupled to the pad 15 or the wiring of the wiring layer 111. For example, as illustrated in FIG. 6A, the connection pad 35 may be directly coupled to the pad 15. In an embodiment illustrated in FIG. 6A, the connection pad 35 is provided around the opening 25. The connection pad 35 extends in the Z-axis direction around the opening 25 and is coupled to the pad 15. The connection pad 35 is also a via coupled to the pad 15, and is also a pad adapted for bonding.

As illustrated in FIG. 6B, the connection pad 35 may be provided inside the opening 25. The connection pad 35 extends in the Z-axis direction in the opening 25 and is coupled to the pad 15. Further, for example, as illustrated in FIG. 6C, the connection pad 35 may be directly coupled to the wiring 17 in the insulating film 92 of the wiring layer 111. Further, as illustrated in FIG. 6D, the connection pad 35 may be directly coupled to the wiring 18 in the insulating film 91 of the wiring layer 111. Also in a case of the present modification example, it is possible to obtain similar effects to those of the above-described embodiment.

### (2-3. Third Modification Example)

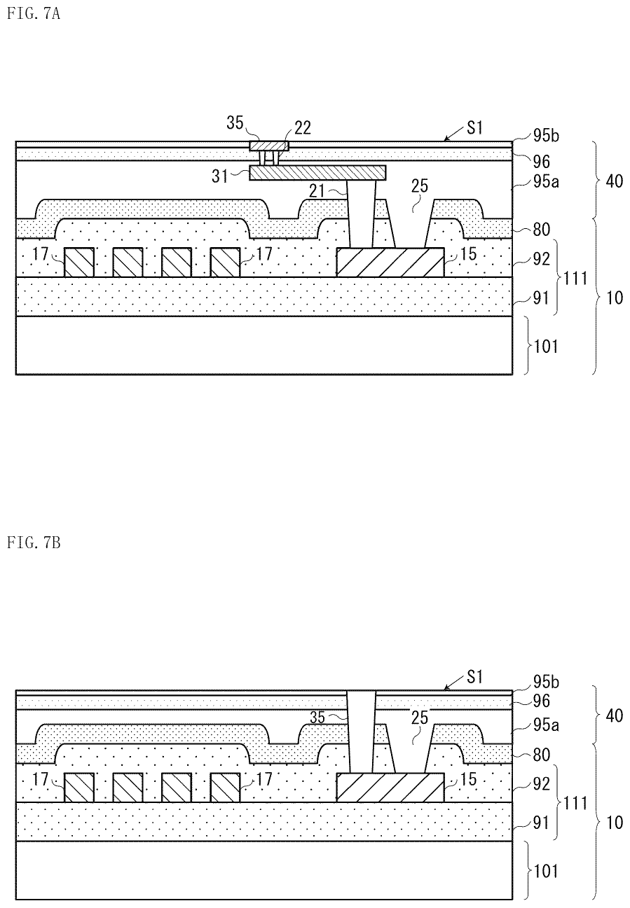

The rewiring layer 40 of the semiconductor device 1 may have a structure in which insulating films are stacked. FIG. 7A is a diagram illustrating a configuration example of a semiconductor device according to a third modification example. As illustrated in FIG. 7A, the rewiring layer 40 includes an insulating film 95a, an insulating film 96, and an insulating film 95b having the flat surface S1. A part of the connection pad 35 is provided inside the insulating film 96. It should be noted that, as illustrated in an example of FIG. 7B, the connection pad 35 may be directly coupled to the pad 15. Further, the connection pad 35 may be directly coupled to the wiring of the wiring layer 111.

### (2-4. Fourth Modification Example)

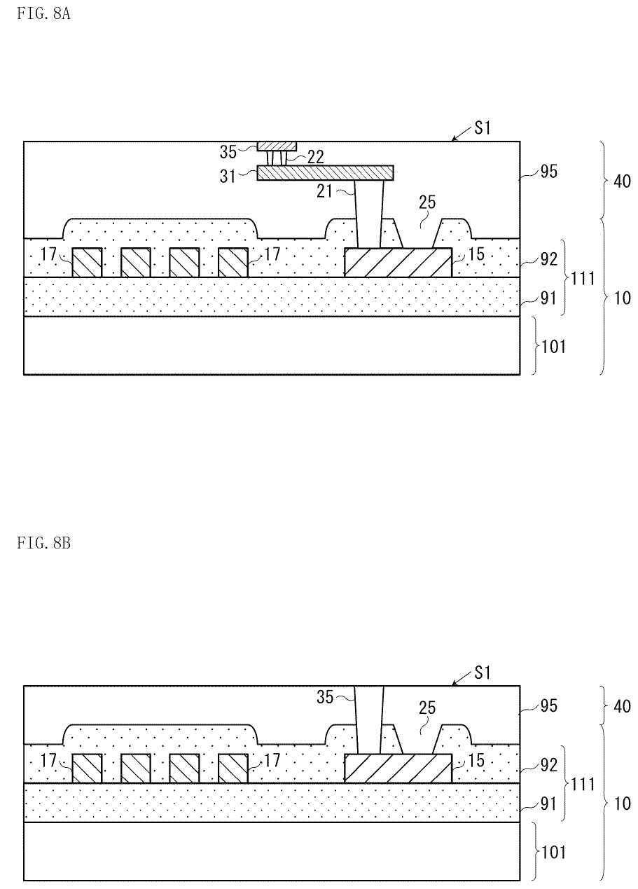

FIGS. 8A and 8B are diagrams illustrating a configuration example of a semiconductor device according to a fourth modification example. As illustrated in FIGS. 8A and 8B, the protective film 80 may not be provided in the semiconductor device 1. It should be noted that the connection pad 35 may be coupled to the pad 15 through the rewiring 31 as in an example illustrated in the FIG. 8A, or may be directly coupled to the pad 15 as in an example illustrated in FIG. 8B, for example.

### (2-5. Fifth Modification Example)

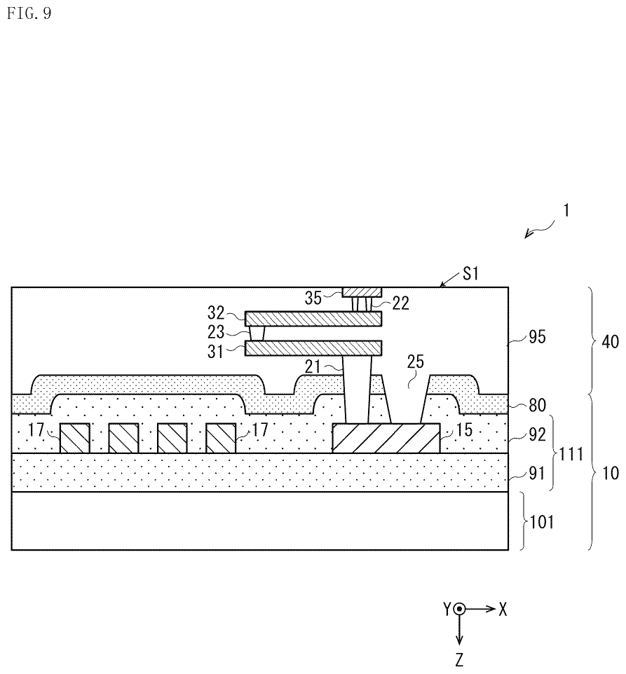

The rewiring layer 40 of the semiconductor device 1 may have multiple rewiring layers. FIG. 9 is a diagram illustrating a configuration example of a semiconductor device according to a fifth modification example. The rewiring layer 40 has two layers of rewirings (in FIG. 9, the rewirings 31 and 32). The rewiring 31 and the rewiring 32 are provided in different layers from each other. The via 23 illustrated in FIG. 9 electrically couples the rewiring 31 and the rewiring 32. The connection pad 35 is electrically coupled to the pad 15 through the via 22, the rewiring 32, the via 23, the rewiring 31, and the via 21.

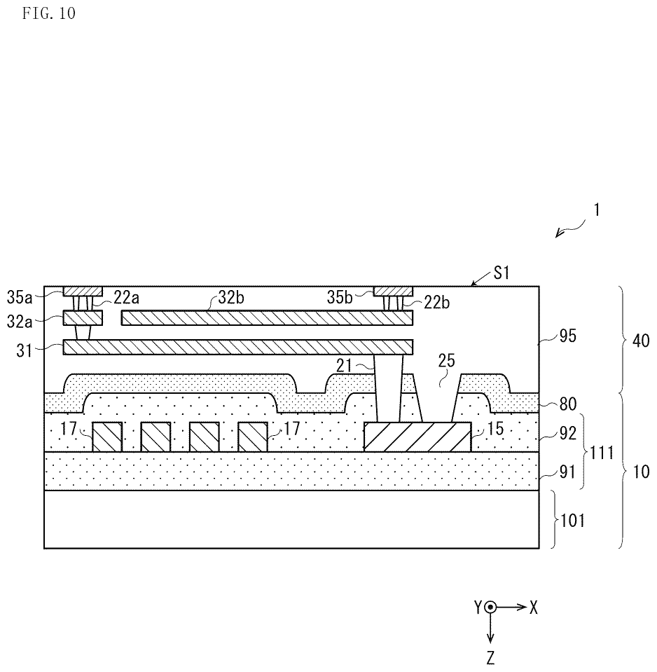

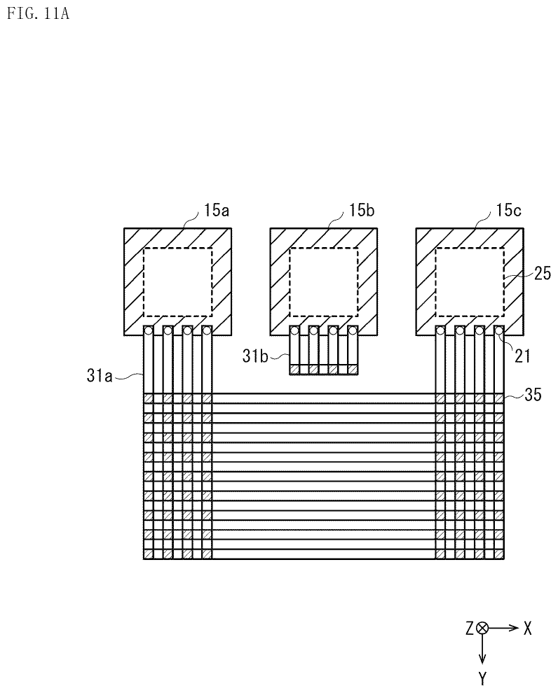

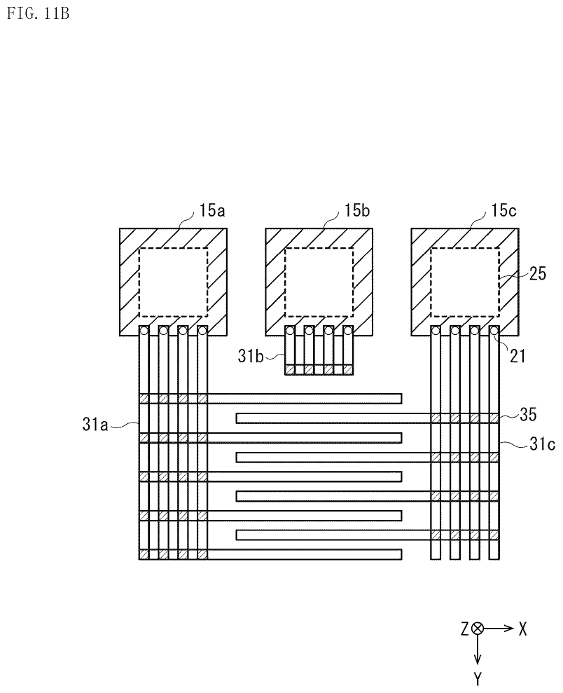

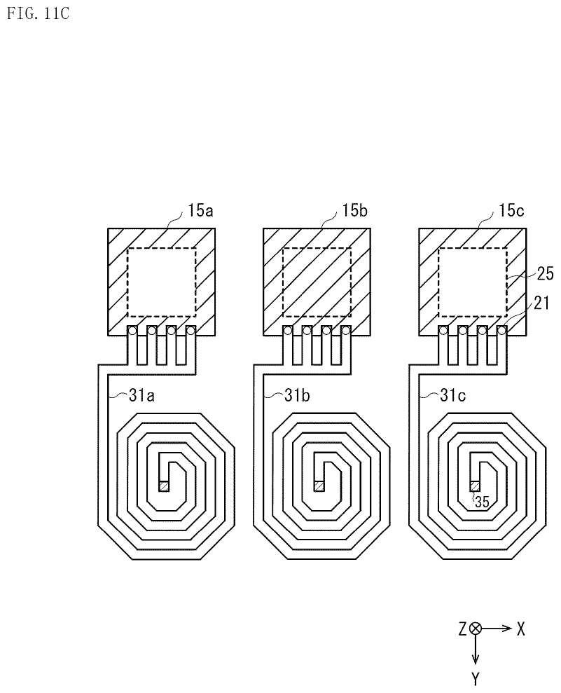

It should be noted that the semiconductor device 1 may include a capacitive element formed by the plurality of rewirings of the rewiring layer 40. FIG. 10 is a diagram illustrating another configuration example of a semiconductor device according to a fifth modification example. In an example illustrated in FIG. 10, the rewiring layer 40 includes rewirings 31, 32a, and 32b. As illustrated in FIG. 10, the rewiring 31 and the rewiring 32b are so provided as to be opposed each other, and the semiconductor device 1 includes the capacitive element configured by the rewiring 31 and the rewiring 32b that are opposed to each other. Thus, for example, it is possible to add a capacitor between the rewiring 31 and the rewiring 32b between the power supply pad and GND pad.
FIGS. 11A to 11C are diagrams for describing an example of a layout of the rewiring of the semiconductor device according to the fifth modification example. As illustrated in FIG. 11A, a common pad (terminal) may be electrically connected by the rewiring. For example, common pads 15a and 15c serving as the power supply pad (or the GND pad) may be electrically coupled by the rewiring 31a.

In addition, as described above, the capacitive element may be formed by the plurality of rewirings. For example, as illustrated in an example of FIG. 11B, the rewiring 31a and the rewiring 31c may be disposed in a scribe shape to provide the capacitive element. In an example illustrated in the FIG. 11B, it is possible to couple a capacitor configured by the rewiring 31a and the rewiring 31c between the pad 15a, which is the power supply pad and the pad 15c which is the GND pad, for example.

It should be noted that the plurality of rewirings may be used to form an inductor. In an example illustrated in FIG. 11C, the rewirings 31a, 31b, 31c are formed in a spiral shape, and the semiconductor device 1 includes the inductor configured by the rewiring formed in the spiral shape. It is possible to form the inductor for any pad.

Although the present disclosure has been described with reference to the embodiments and the modification examples, the present technology is not limited to the above-described embodiments and the like, and various modifications are possible. For example, the above-described modification examples have been described as modification examples of the above-described embodiment, but it is possible to combine the configuration of each modification example as appropriate.

A semiconductor device according to one embodiment of the present disclosure includes: a semiconductor chip including a first pad, a first wiring, and a first insulating film; a second insulating film provided on the semiconductor chip and having a flat surface; and a second pad provided on the second insulating film and including a metal material. The second pad is electrically coupled to the first pad or the first wiring, and is provided up to the surface of the second insulating film. Thus, it is possible to use various semiconductor chips, such as general-purpose memories, for performing the bonding between the metal electrodes, for example, the Cu—Cu bonding. It is possible to provide a semiconductor device suitable for bonding between metal electrodes.

It is to be noted that the effects described in the present specification are mere examples and description thereof is non-limiting. Other effects may be also provided. Further, the present disclosure can have the following configuration.

(1)

A semiconductor device including:
a semiconductor chip including a first pad, a first wiring, and a first insulating film;
a second insulating film provided on the semiconductor chip and having a flat surface; and
a second pad provided on the second insulating film and including a metal material, in which
the second pad is electrically coupled to the first pad or the first wiring, and is provided up to the surface of the second insulating film.
   (2)

The semiconductor device according to (1), further including a rewiring provided inside the second insulating film, in which
the second pad is electrically coupled to the first pad via the rewiring.
   (3)

The semiconductor device according to (2), further including:
a first via electrically coupling the first pad and the rewiring; and
a second via electrically coupling the second pad and the rewiring, in which

a size of the first via is larger than a size of the second via.

(4)

The semiconductor device according to any one of (1) to (3), in which the first insulating film is provided to cover at least a part of each of the first pad and the first wiring.

(5)

The semiconductor device according to any one of (1) to (4), in which
the first insulating film has an opening provided on the first pad, and
the first via is provided around the opening.
   (6)

The semiconductor device of (5), in which the first pad has a needle mark inside the opening.

(7)

The semiconductor device according to any one of (1) to (6), in which
the first insulating film has an opening provided on the first pad, and
the first via is provided inside the opening.
   (8)

The semiconductor device according to any one of (1) to (7), in which
the first pad and the first wiring are provided in different layers from each other, and
the second pad is electrically coupled to the first wiring.
   (9)

The semiconductor device according to any one of (1) to (8), further including a third insulating film provided between the semiconductor chip and the second insulating film, in which
at least a part of the second pad is provided inside the third insulating film.
   (10)

The semiconductor device according to any one of (1) to (9), further including a first rewiring and a second rewiring provided in different layers from each other, in which
the second pad is electrically coupled to the first pad via the first rewiring and the second rewiring.
   (11)

The semiconductor device according to any one of (1) to (10), further including a capacitive element configured by a first rewiring and a second rewiring that are opposed to each other, in which
the first rewiring and the second rewiring are electrically coupled to different pads from each other.
   (12)

The semiconductor device according to any one of (1) to (11), further including an inductor configured by a rewiring formed in a spiral shape, in which
the second pad is electrically coupled to the first pad via the rewiring.
   (13)

The semiconductor device according to any one of (1) to (12), in which
the first insulating film has an opening provided on the first pad, and
the second pad is directly coupled to the first pad around the opening.
   (14)

The semiconductor device according to any one of (1) to (13), in which
the first insulating film has an opening provided on the first pad, and
the second pad is directly coupled to the first pad inside the opening.
   (15)

The semiconductor device according to any one of (1) to (14), in which the second pad is directly coupled to the first wiring.

(16)

The semiconductor device according to any one of (1) to (15), in which the second pad includes copper.

(17)

The semiconductor device according to any one of (1) to (16), in which the semiconductor chip includes a plurality of the first wirings provided with an air gap therebetween.

(18)

The semiconductor device according to any one of (1) to (17), in which the second insulating film includes at least one of an oxide film or a nitride film.

(19)

The semiconductor device according to any one of (1) to (18), further including a protective film provided between the first insulating film and the second insulating film.

(20)

The semiconductor device according to any one of (1) to (19), in which the semiconductor chip is a general-purpose memory, a general-purpose logic, or a custom design chip.

(21)

A laminated structure including: a semiconductor substrate;
a wiring layer stacked on the semiconductor substrate; and
a semiconductor device stacked on the wiring layer,
the semiconductor device including:
   a semiconductor chip including a first pad, a first wiring, and a first insulating film;
   a second insulating film provided on the semiconductor chip and having a flat surface; and
   a second pad provided on the second insulating film and including a metal material, in which
the second pad is electrically coupled to the first pad or the first wiring, and is provided up to the surface of the second insulating film, and
the wiring layer has a third pad bonded to the second pad.
   (22)

The laminated structure according to (21), in which the semiconductor substrate includes a photoelectric converter.

The present application claims the benefit of Japanese Priority Patent Application JP2022-106529 filed with the Japan Patent Office on Jun. 30, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device, comprising:
a semiconductor chip including a first pad, a first wiring, and a first insulating film;
a second insulating film provided on the semiconductor chip and having a flat surface; and
a second pad provided on the second insulating film and including a metal material, wherein
the second pad is electrically coupled to the first pad or the first wiring, and is provided up to the surface of the second insulating film.

2. The semiconductor device according to claim 1, further comprising a rewiring provided inside the second insulating film, wherein
the second pad is electrically coupled to the first pad via the rewiring.

3. The semiconductor device according to claim 2, further comprising:
a first via electrically coupling the first pad and the rewiring; and
a second via electrically coupling the second pad and the rewiring, wherein
a size of the first via is larger than a size of the second via.

4. The semiconductor device according to claim 3, wherein the first insulating film is provided to cover at least a part of each of the first pad and the first wiring.

5. The semiconductor device according to claim 3, wherein
the first insulating film has an opening provided on the first pad, and
the first via is provided around the opening.

6. The semiconductor device of claim 5, wherein the first pad has a needle mark inside the opening.

7. The semiconductor device according to claim 3, wherein
the first insulating film has an opening provided on the first pad, and
the first via is provided inside the opening.

8. The semiconductor device according to claim 1, wherein
the first pad and the first wiring are provided in different layers from each other, and
the second pad is electrically coupled to the first wiring.

9. The semiconductor device according to claim 1, further comprising a third insulating film provided between the semiconductor chip and the second insulating film, wherein
at least a part of the second pad is provided inside the third insulating film.

10. The semiconductor device according to claim 1, further comprising a first rewiring and a second rewiring provided in different layers from each other, wherein
the second pad is electrically coupled to the first pad via the first rewiring and the second rewiring.

11. The semiconductor device according to claim 1, further comprising a capacitive element configured by a first rewiring and a second rewiring that are opposed to each other, wherein
the first rewiring and the second rewiring are electrically coupled to different pads from each other.

12. The semiconductor device according to claim 1, further comprising an inductor configured by a rewiring formed in a spiral shape, wherein
the second pad is electrically coupled to the first pad via the rewiring.

13. The semiconductor device according to claim 1, wherein
the first insulating film has an opening provided on the first pad, and
the second pad is directly coupled to the first pad around the opening.

14. The semiconductor device according to claim 1, wherein
the first insulating film has an opening provided on the first pad, and
the second pad is directly coupled to the first pad inside the opening.

15. The semiconductor device according to claim 1, wherein the second pad is directly coupled to the first wiring.

16. The semiconductor device according to claim 1, wherein the second pad includes copper.

17. The semiconductor device according to claim 1, wherein the semiconductor chip includes a plurality of the first wirings provided with an air gap therebetween.

18. The semiconductor device according to claim 1, wherein the second insulating film includes at least one of an oxide film or a nitride film.

19. The semiconductor device according to claim 1, further comprising a protective film provided between the first insulating film and the second insulating film.

20. The semiconductor device according to claim 1, wherein the semiconductor chip comprises a general-purpose memory, a general-purpose logic, or a custom design chip.

21. A laminated structure, comprising: a semiconductor substrate;
a wiring layer stacked on the semiconductor substrate; and
a semiconductor device stacked on the wiring layer,
the semiconductor device including:
a semiconductor chip including a first pad, a first wiring, and a first insulating film;
a second insulating film provided on the semiconductor chip and having a flat surface; and
a second pad provided on the second insulating film and including a metal material, wherein
the second pad is electrically coupled to the first pad or the first wiring, and is provided up to the surface of the second insulating film, and
the wiring layer has a third pad bonded to the second pad.

22. The laminated structure according to claim 21, wherein the semiconductor substrate includes a photoelectric converter.
